(19) United States
(12) Patent Application Publication
(10) Pub. No.: US 2025/0096074 A1
(43) Pub. Date: Mar. 20, 2025

(54) BACKSIDE OFFSET GATE CONTACT FOR BACKSIDE SPACING

(71) Applicant: International Business Machines Corporation, Armonk, NY (US)

(72) Inventors: Ruilong Xie, Niskayuna, NY (US); Albert M Chu, Nashua, NH (US); Brent A. Anderson, Jericho, VT (US); Lawrence A. Clevenger, Saratoga Springs, NY (US)

(21) Appl. No.: 18/468,729

(22) Filed: Sep. 17, 2023

(51) Int. Cl. H01L 23/48; H01L 21/8238; H01L 27/092; H01L 29/06; H01L 29/417; H01L 29/423; H01L 29/66; H01L 29/775; H01L 29/786

(52) U.S. Cl. CPC H01L 23/481; H10D 30/014; H10D 30/43; H10D 30/6729; H10D 30/6735; H10D 30/6757; H10D 62/121; H10D 84/017; H10D 84/0186; H10D 84/038; H10D 84/85

(57) ABSTRACT

Embodiments disclosed herein include a semiconductor structure. The semiconductor structure may include a front-end-of-line (FEOL) including a first source/drain (S/D) adjacent to a first gate. A device may include a backside interconnect below the FEOL, with a plurality of signal lines and a plurality of power lines. A device may include an offset gate contact electrically connected between the first gate and a first signal line of the plurality of signal lines, wherein the offset gate contact is located directly below the first S/D.

### BACKGROUND

The present invention relates generally to the field of interconnects in a semiconductor structure, and more particularly to a backside offset gate contact for improving the spacing of a first level backside metal layer.

A backside interconnect, also known as a backside bus, refers to the physical infrastructure that connects various components of a computer or electronic system on the reverse side (opposite the front side) of an integrated circuit (IC). Backside interconnects can be used to facilitate communication or power distribution among different components, such as processors, memory modules, and peripheral devices. Designs of ICs should take into account a number of considerations such as: signal routing and communication, power distribution, thermal dissipation and accumulation, electromagnetic compatibility, routing topology and layout, and advanced packaging techniques. Fully utilizing a backside interconnect for either signal or power involves careful consideration of signal integrity, power distribution, thermal management, and EMC.

### SUMMARY

In some aspects, the techniques described herein relate to a semiconductor structure, including: a front-end-of-line (FEOL) including a first source/drain (S/D) adjacent to a first gate; a backside interconnect below the FEOL, including a plurality of signal lines and a plurality of power lines; an offset gate contact electrically connected between the first gate and a first signal line of the plurality of signal lines, wherein the offset gate contact is located directly below the first S/D.

In some aspects, the techniques described herein relate to a method, including: forming a front-end-of-line (FEOL) including a first source/drain (S/D) and a first gate; forming an offset gate contact electrically connected between the first gate and a first signal line, wherein the offset gate contact is located directly below the first S/D.

In some aspects, the techniques described herein relate to a semiconductor structure, including: a first gate; a first source/drain (S/D) adjacent to the first gate, and connected to a back-end-of-line (BEOL) through a S/D contact directly above the first S/D; an offset gate contact electrically connected between the first gate and a first level signal line, wherein the offset gate contact is located directly below the first S/D.

### BRIEF DESCRIPTION OF THE DRAWINGS

FIG. 1 depicts a cross-sectional side view of a semiconductor structure with a front-end-of-line (FEOL) and a back-end-of-line (BEOL).

FIG. 2 is a schematic cross-sectional side view of the semiconductor structure at a fabrication step, in accordance with one embodiment of the present invention.

FIG. 3 is a schematic cross-sectional side view of the semiconductor structure at a fabrication step, in accordance with one embodiment of the present invention.

FIG. 4 is a schematic cross-sectional side view of the semiconductor structure at a fabrication step, in accordance with one embodiment of the present invention.

FIG. 5 is a schematic cross-sectional side view of the semiconductor structure at a fabrication step, in accordance with one embodiment of the present invention.

FIG. 6 is a schematic cross-sectional side view of the semiconductor structure at a fabrication step, in accordance with one embodiment of the present invention.

FIG. 7 is a schematic cross-sectional side view of the semiconductor structure at a fabrication step, in accordance with one embodiment of the present invention.

FIG. 8 is a schematic cross-sectional side view of the semiconductor structure at a fabrication step, in accordance with one embodiment of the present invention.

FIG. 9 is a schematic cross-sectional side view of the semiconductor structure at a fabrication step, in accordance with one embodiment of the present invention.

FIG. 10 is a schematic cross-sectional side view of the semiconductor structure at a fabrication step, in accordance with one embodiment of the present invention.

FIG. 11 is a schematic cross-sectional side view of the semiconductor structure at a fabrication step, in accordance with one embodiment of the present invention.

FIG. 12 is a schematic cross-sectional side view of the semiconductor structure at a fabrication step, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “adjacent,” “directly on,” or “directly over” another element, there are no intervening elements present. It will also be understood that when an element is referred to as being “beneath” or “under” another element, it can be directly below or under the other element, or intervening elements may be present. Additionally, when an element is referred to as being “directly below” or “directly above” another element, intervening elements may be present, but the elements overlap at least partially relative to a vertical axis perpendicular to a major surface. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated. Each reference number may refer to an item individually or collectively as a group. For example, a contact 202 may refer to a single contact 202 or multiple contacts 202.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

Semiconductor structures control power flow between source/drains (S/Ds) using a signal to a gate. Power lines within an integrated circuit convey the power to the S/Ds, while signal lines convey the signals to the gates. Embodiments herein recognize that integrating power and signal lines closely together improves the speed and efficiency of these semiconductor structures, especially in a backside interconnect. Condensing the power and signal lines, however, can cause problems that sometimes result in defects. Specifically, in cases where fabrication tolerances mean that one of the lines (i.e., power/signal lines) ends up too close to another of the lines, then tip-to-tip shorting may cause unintended flow between the lines. Increasing the tip-to-tip distance, however, can cause the lines to create insufficient electrical connection to the contact below the line (i.e., the contact that connects the lines to the S/D or the gate). The embodiments herein, therefore, include a semiconductor structure with an offset gate contact electrically connected between the first gate and a first signal line of the plurality of signal lines, wherein the offset gate contact is located directly below the first S/D.

The embodiments described below include various semiconductor structures. The semiconductor structures may include a front-end-of-line (FEOL) with a first source/drain (S/D) adjacent to a first gate and a backside interconnect below the FEOL. The backside interconnect may include a plurality of signal lines and a plurality of power lines, with the technical benefit of higher density and thus greater efficiency and smaller overall size of the semiconductor structure. The semiconductor structure may also include an offset gate contact electrically connected between the first gate and a first signal line of the plurality of signal lines. The offset gate contact may be located directly below the first S/D to provide the technical benefit of increasing a tip-to-tip distance between the first signal line and a first power line.

In certain embodiments, the semiconductor structure may include a frontside back-end-of-line (BEOL) above the FEOL, the frontside BEOL may signal processing layers. The frontside BEOL is opposite the backside interconnect, which provides the technical benefit of higher density and more compact connection with the FEOL. Certain embodiments may also include a backside gate extension directly below the first gate, and electrically connected between the first gate and the offset gate contact, which can provide a more stable connection between the offset gate contact and the first gate. Further embodiments may include a backside gate extension cap directly below the backside gate extension to insulate the backside gate extension from the backside interconnect.

Certain embodiments may include a backside S/D dielectric below the first S/D. The backside S/D dielectric and the backside gate extension cap may include different dielectric materials to enable selective etch between the backside S/D dielectric and the backside gate extension cap. Certain embodiments may also include a second S/D adjacent to the first gate. The second S/D may be electrically connected to the backside interconnect through a S/D contact directly below the second S/D to power the second S/D through the backside interconnect. Certain embodiments may also include a spacer and a backside gate extension cap between the S/D contact and the offset gate contact to increase insulation.

Certain embodiments of the disclosed invention may also include a method of fabricating a semiconductor structure. The method may include forming a front-end-of-line (FEOL) with a first source/drain (S/D) and a first gate, and forming an offset gate contact electrically connected between the first gate and a first signal line. The offset gate contact is located directly below the first S/D to provide the technical benefit of increasing a tip-to-tip distance between the first signal line and a first power line.

Certain embodiments of the method may also include forming a frontside back-end-of-line (BEOL) above the FEOL that include signal processing layers, which provides the technical benefit of higher density and more compact connection with the FEOL. Certain embodiments may further include forming a backside gate extension below the first gate. The offset gate contact contacts a lateral side of the backside gate extension, which can provide a more stable connection between the offset gate contact and the first gate. Certain embodiments may also deposit a first dielectric material below the first S/D, and deposit a second dielectric material below the backside gate extension so that the first dielectric material is etch selective from the second dielectric material. Certain embodiments of the method may also form a bottom spacer between the backside gate extension and the first dielectric material to insulate the backside gate extension form the first dielectric material and prevent shorting and defects. Certain embodiments of the method may also form a bottom S/D contact below a second S/D adjacent to the first gate to connect the second S/D to the backside interconnect.

Certain embodiments of the present invention may include semiconductor structures that have a first gate and a first source/drain (S/D) adjacent to the first gate. The first S/D may be connected to a back-end-of-line (BEOL) through a S/D contact directly above the first S/D. The semiconductor structure may also include an offset gate contact electrically connected between the first gate and a first level signal line. The offset gate contact is located directly below the first S/D to provide the technical benefit of increasing a tip-to-tip distance between the first signal line and a first power line.

Certain embodiments may also include a backside gate extension directly below the first gate, and electrically connected between the first gate and the offset gate contact, which can provide a more stable connection between the offset gate contact and the first gate. Certain embodiments may include a backside gate extension cap directly below the backside gate extension to insulate the backside gate extension from the backside interconnect. Certain embodiments may include a backside S/D dielectric below the first S/D. The backside S/D dielectric and the backside gate extension cap comprise different dielectric materials to enable selective etch between the backside S/D dielectric and the backside gate extension cap.

Certain embodiments of the semiconductor structure include a second S/D adjacent to the first gate. The second S/D may be electrically connected to a first level power line through a S/D contact directly below the second S/D to connect the second S/D to the backside interconnect. Certain embodiments may also include a bottom spacer and a backside gate extension cap between the S/D contact and the offset gate contact to insulate the backside gate extension from the backside interconnect. Certain embodiments may also include a first level signal line and a first level power line. A tip-to-tip distance between the first level signal line and the first level power line may be greater than a width of the first gate to decrease the likelihood of shorting and defects between the first level signal line and the first level power line.

The present invention and an example fabrication process will now be described in detail with reference to the Figures.

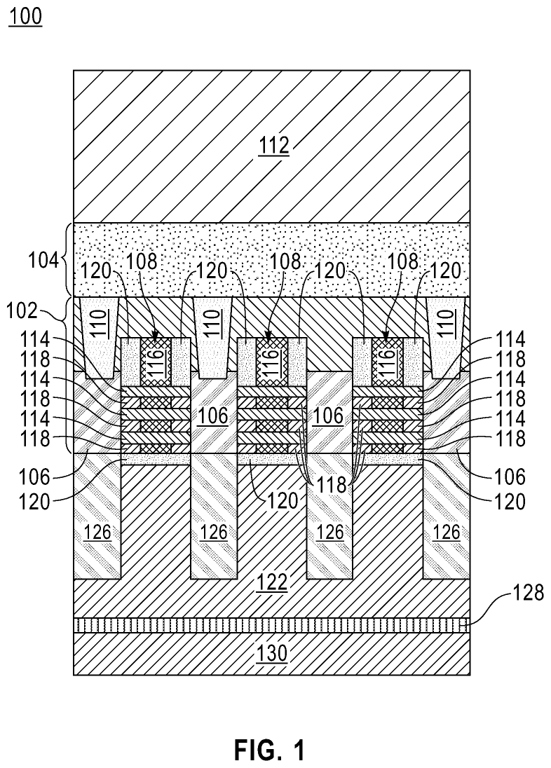

FIG. 1 depicts a cross-sectional side view of a semiconductor structure 100 front-end-of-line (FEOL) 102 and a frontside back-end-of-line (BEOL) 104. The FEOL 102 includes source/drains (S/Ds) 106 and gates 108, with contacts 110 connecting the S/Ds 106 to the BEOL 104. The BEOL 104 is not drawn to scale, and may include many layers of power and signal lines connecting the FEOL 102 to external devices and controls. The FEOL 102 may include NFET and PFET regions arranged in rows and columns containing thousands or millions of transistors. In certain embodiments, the FEOL 102 is fabricated in one vertical orientation (and completed) before the semiconductor structure 100 is flipped over with the BEOL 104 being fabricated in the opposite vertical orientation. In other embodiments, the FEOL 102 and BEOL 104 are fabricated in the same orientation, and a carrier wafer 112 is added to strengthen the semiconductor structure 100 before flipping and continued fabrication on the backside. The carrier wafer 112 strengthens the semiconductor structure 100 so the FEOL 102 and BEOL 104 will not flex or bend, which can cause damage. In certain embodiments, the carrier wafer 112 may be bonded to the BEOL 104 through dielectric-dielectric bonding or Cu—Cu bonding. The figures in this description will maintain the orientation with the carrier wafer 112 at the top, but it should be understood that the illustrated fabrication stages may be completed with a different orientation (e.g., with the carrier wafer 112 on the bottom).

The FEOL 102 may be fabricated using some known techniques for forming the gates 108 and the S/Ds 106. While no specific type of gate is necessary to be used with the offset gate contacts described below, and various types of gates 108 may be used within the scope of the embodiments described herein, the gates 108 in the illustrated embodiment include nanosheets 114. The nanosheets 114 may be fabricated initially as blanket layers separated by dummy layers. The nanosheets 114 and dummy layers may then be etched using patterning process that is applied using a hard mask (not illustrated) to define the active regions by conventional lithographical processes. Then the areas that are not protected by the hard mask may be etched away, followed by forming shallow trench isolation (STI) regions (not illustrated) to separate different active regions. After that, dummy gates are formed, which are later replaced by a high-k metal gate (HKMG) 116. The HKMG 116 is insulated from the S/Ds 106 by inner spacers 118 and upper spacers 120. The S/Ds 106 may be fabricated using epitaxial growth.

The FEOL 102 is fabricated on a substrate 122 typically including silicon, but other materials may be used. The gates 108 are separated from the substrate 122 by a bottom dielectric isolation (BDI) 124. In certain embodiments, the substrate 122 may also include backside contact placeholders 126. The backside contact placeholders 126 may be formed after the dummy gate and gate spacers 120 are formed. After that, S/D epi 106 can be grown over the placeholder 126. The substrate 122 may also include an etch stop layer 128 that aids in removal of the substrate 122. Specifically, the etch stop layer 128 enables a rough etch process to remove a lower portion 130 of the substrate 122 (typically much thicker than what is illustrated in FIG. 1) quickly, and then stop at the etch stop layer 128 before accidentally etching other components (e.g., the backside contact placeholders 126). Example materials of the etch stop layer 128 can be a SiGe or SiO2.

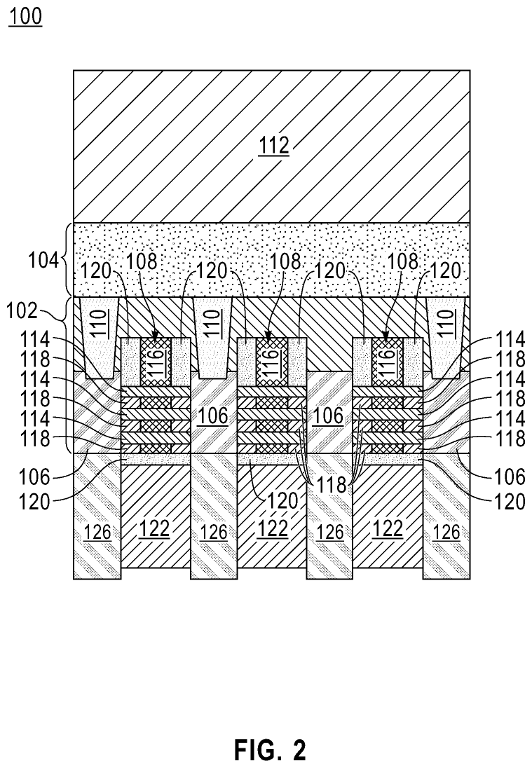

FIG. 2 is a schematic cross-sectional side view of the semiconductor structure 100 at a fabrication step, in accordance with one embodiment of the present invention. The rough etch process (just discussed above) has been completed, removing the lower portion 130 of the substrate 122 and stopping on etch stop layer 128. After that, additional etch processes have also been used to remove the etch stop layer 128 and to partially recess the substrate 122. The recessing of the substrate 122 may include a selective etch process that wears down the silicon of the substrate 122 to reveal the backside contact placeholders 126, which may be formed from a silicon-germanium (SiGe). The difference in material enables the etching of the substrate 122 to be completed without wearing the backside contact placeholders 126 down or otherwise affecting the backside contact placeholders 126.

As a reiteration of the description above, the steps of rough etching the lower portion 130, removing the etch stop layer 128, and recessing the substrate 122 may be done with the semiconductor structure 100 in the flipped orientation. The lower portion 130 therefore, may actually be removed as the upper-most layer of the semiconductor structure 100, and the description here is merely given with regard to the orientation of the Figures, and does not limit the orientation of the semiconductor structure 100 at any stage of actual fabrication.

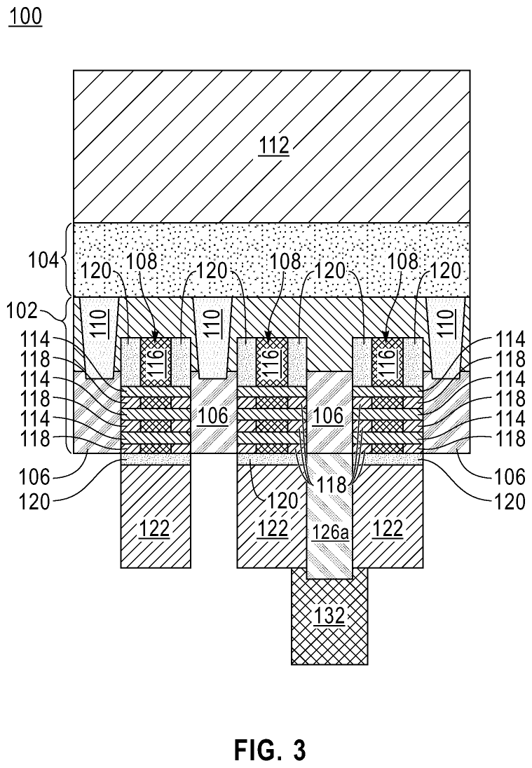

FIG. 3 is a schematic cross-sectional side view of the semiconductor structure 100 at a fabrication step, in accordance with one embodiment of the present invention. The semiconductor structure 100 at this stage includes a patterning mask, such as an organic planarization layer (OPL) 132 that has been patterned to cover one of the backside contact placeholders 126. This protected backside contact placeholder 126a is shielded by the OPL 132 from a selective etch process that removes the remaining backside contact placeholders 126. The etch process used to remove the backside contact placeholders 126 is selectively reversed from the etch process that recessed the substrate 122. Specifically, the etch process used to remove the backside contact placeholders 126 removes SiGe without affecting the purer silicon of the substrate 122. The protected backside contact placeholder 126a is located over a protected S/D 106a such that the protected S/D 106a is not exposed, while the remaining S/Ds 106 are exposed by the resulting voids in the substrate 122.

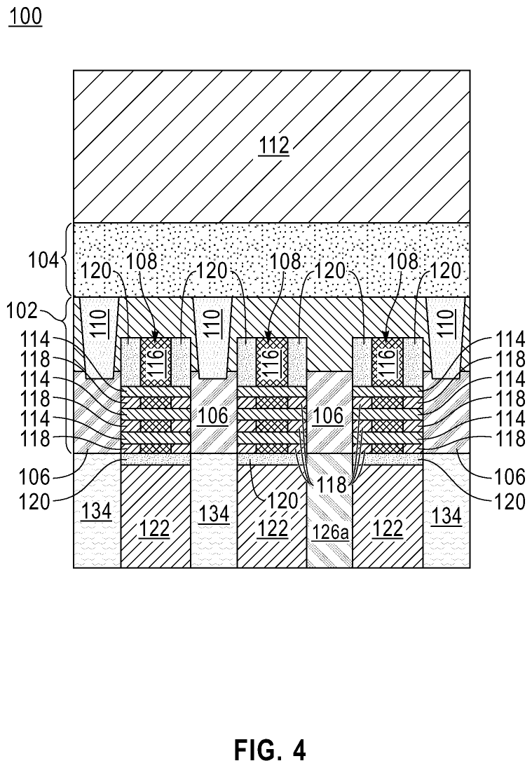

FIG. 4 is a schematic cross-sectional side view of the semiconductor structure 100 at a fabrication step, in accordance with one embodiment of the present invention. The semiconductor structure 100 at this stage includes a first dielectric material 134 filled into the voids vacated by the etched backside contact placeholders 126. The first dielectric material 134 may be characterized as a backside S/D dielectric below the S/Ds 106. The first dielectric material 134 may include materials such as a non-crystalline solid material such as SiN, SiC, SiCN(H), or other silicon compounds for insulating, silicon dioxide (SiO2) undoped silicate glass (USG), tetraethyl orthosilicate (TEOS), low-K dielectric, or ultra low-K dielectric materials, fluorosilicate glass (FSG), borophosphosilicate glass (BPSG), a spin-on low-K dielectric layer, a chemical vapor deposition (CVD) low-K dielectric layer or any combinations thereof. The protected backside contact placeholder 126a remains in place covering the protected S/D 106a. The OPL 132 may be ashed and removed. The ashing process may involve subjecting the OPL 132 to high temperatures in the presence of oxygen or other reactive gases. This causes the organic materials to break down and oxidize, leaving behind only the inorganic residues. The exact parameters of the ashing process, such as temperature, duration, and gas environment, can vary depending on the specific materials used in the organic layer and the desired outcome. After ashing, the semiconductor structure 100 can be left with a well-defined planar surface suitable for further processing, such as deposition of additional layers or patterning. Furthermore, the semiconductor structure 100 may be flattened using a chemical-mechanical planarization (CMP) process.

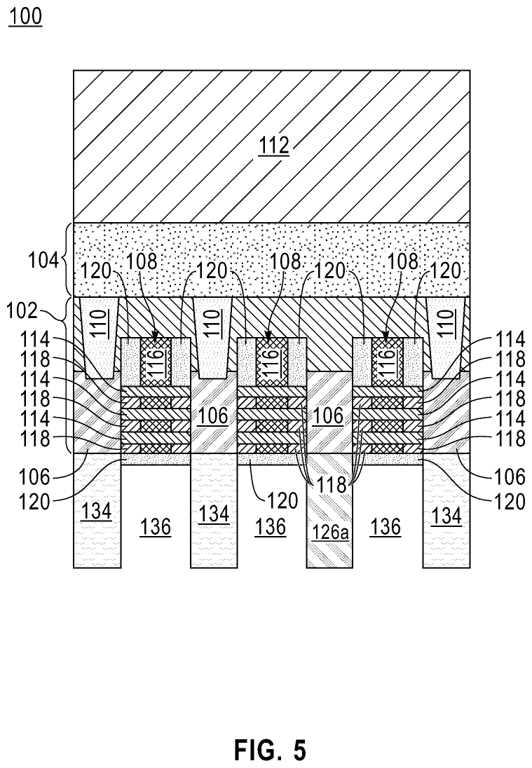

FIG. 5 is a schematic cross-sectional side view of the semiconductor structure 100 at a fabrication step, in accordance with one embodiment of the present invention. The semiconductor structure 100 at this stage includes voids 136 vacated by the silicon of the substrate 122. The substrate 122 is removed by an etch process that is selective to the substrate 122. Thus, the substrate 122 is etched from between the first dielectric material 134, and the first dielectric material 134, the protected backside contact placeholder 126a, and the BDI 124 remain unaffected by the selective etch process.

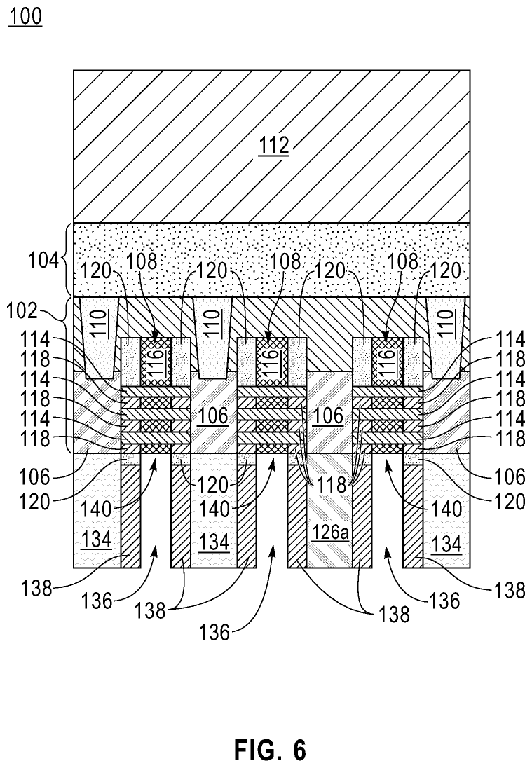

FIG. 6 is a schematic cross-sectional side view of the semiconductor structure 100 at a fabrication step, in accordance with one embodiment of the present invention. The semiconductor structure 100 at this stage includes bottom spacers 138 lining the voids 136 vacated by the removed substrate 122. An etch process may then be used to create a gap 140 in the BDI 124 that exposes the HKMG 116. The bottom spacers 138 may be formed with a thickness that is the same as the inner spacers 118 and upper spacers 120. This uniformity between the dimensions of the spacers 118, 120, 138 means that the HKMG 116 may be exposed with fairly high accuracy: all of the HKMG 116 is exposed with minimal exposure of the inner spacers 118 and no exposure of the S/Ds 106.

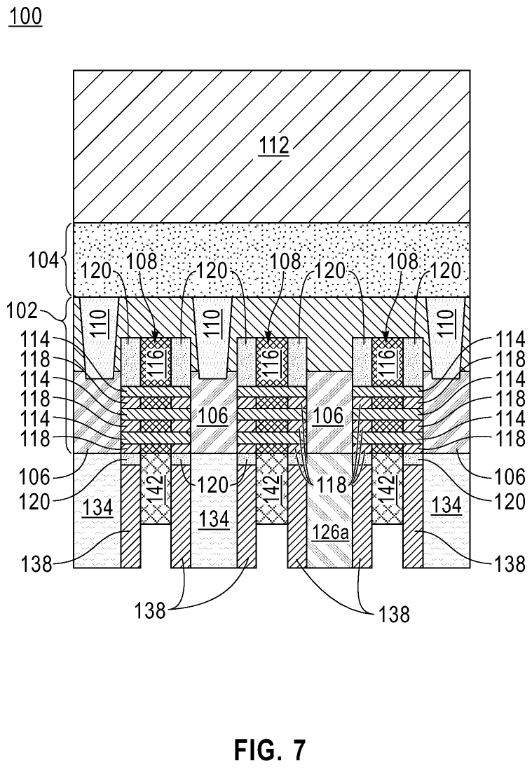

FIG. 7 is a schematic cross-sectional side view of the semiconductor structure 100 at a fabrication step, in accordance with one embodiment of the present invention. The semiconductor structure 100 at this stage includes backside gate extensions 142 filled into the voids 136 and the gaps 140. In certain embodiments, the backside gate extensions 142 do not completely fill the voids 136. The incomplete filling may be accomplished by application of metal onto the semiconductor structure 100 followed by an etch back of the metal through a selective etch process that does not affect the first dielectric material 134 or the bottom spacers 138. Other methods of forming the backside gate extensions 142 may also be used.

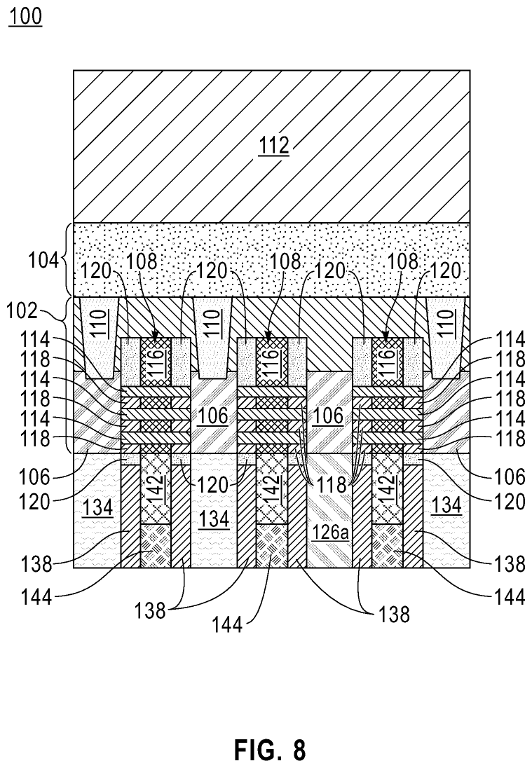

FIG. 8 is a schematic cross-sectional side view of the semiconductor structure 100 at a fabrication step, in accordance with one embodiment of the present invention. The semiconductor structure 100 at this stage includes a second dielectric material 144 filled into the voids 136 below the backside gate extensions 142. The second dielectric material 144 in certain embodiments is fabricated using a different composition than the first dielectric material 134. The second dielectric material 144 may be characterized as a backside gate extension cap directly below the backside gate extension 142 The difference between the materials of the first dielectric material 134 and the second dielectric material 144 may mean that the first dielectric material 134 is selectively etched from the second dielectric material 144 and vice versa. The semiconductor structure 100 may be planarized, for example using CMP, after the second dielectric material 144 is formed.

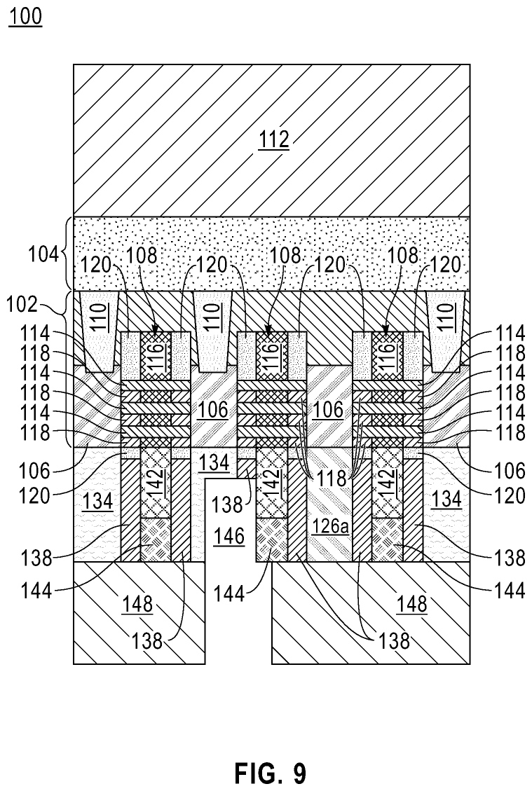

FIG. 9 is a schematic cross-sectional side view of the semiconductor structure 100 at a fabrication step, in accordance with one embodiment of the present invention. The semiconductor structure 100 at this stage includes an offset gate hole 146 patterned through the use of an additional OPL 148. The additional OPL 148 may include a material (e.g., similar to the OPL 132, but not required to be the same material) that is lithographically patterned and etched to form the offset gate hole 146. After the additional OPL 148 is patterned, one or more selective etch processes may be used to remove material from the first dielectric material 134 and bottom spacers 138 but not from the second dielectric material 144 or the backside gate extensions 142. The one or more selective etch processes may include, for example, one etch process to etch the first dielectric material 134 and another etch process to remove the bottom spacers 138. The etch processes may also be completed with the first dielectric material 134 etched first, or with the bottom spacers 138 etched first.

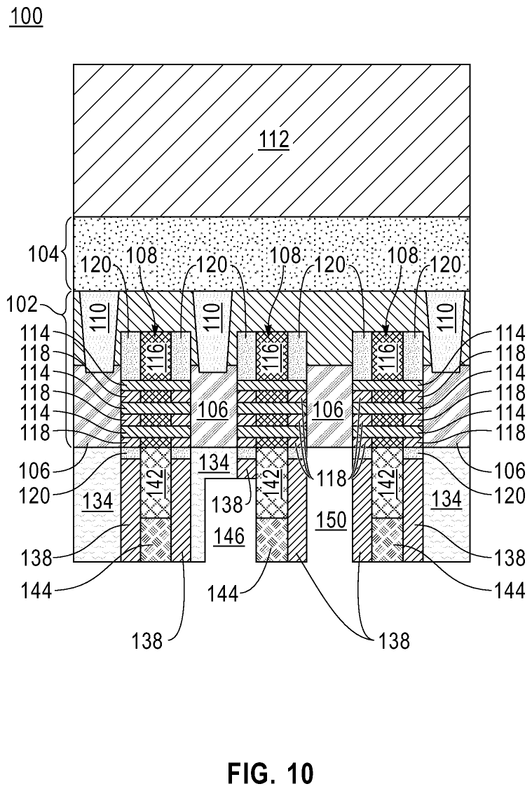

FIG. 10 is a schematic cross-sectional side view of the semiconductor structure 100 at a fabrication step, in accordance with one embodiment of the present invention. The semiconductor structure 100 at this stage includes a S/D contact hole 150 vacated by the etched protected backside contact placeholder 126a. The protected backside contact placeholder 126a may be etched after the additional OPL 148 is removed by ashing the additional OPL 148. Specifically, the protected backside contact placeholder 126a may be removed using a selective etch process that only affects the protected backside contact placeholder 126a. Specifically, the selective etch process does not affect the S/Ds 106, the BDI 124, the first dielectric material 134, the bottom spacers 138, the backside gate extensions 142, or the second dielectric material 144.

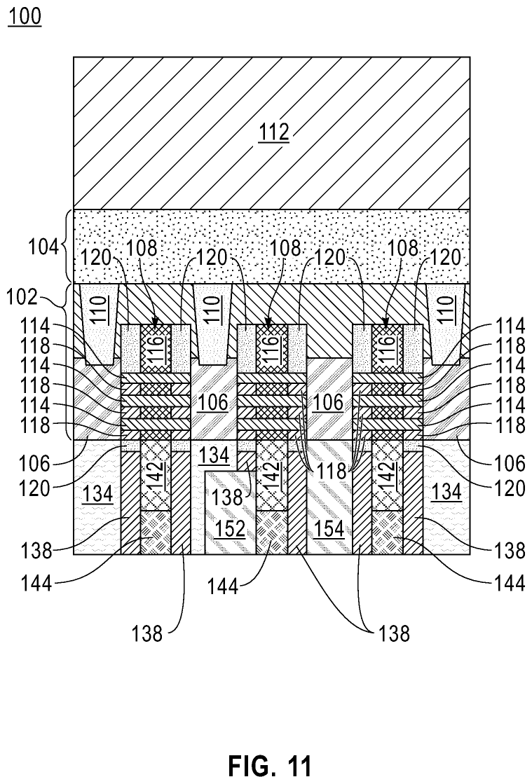

FIG. 11 is a schematic cross-sectional side view of the semiconductor structure 100 at a fabrication step, in accordance with one embodiment of the present invention. The semiconductor structure 100 at this stage includes an offset gate contact 152 filled into the offset gate hole 146 and a bottom S/D contact 154 filled into the S/D contact hole 150. The offset gate contact 152 and the bottom S/D contact 154 may be filled with the same material with the same metal filling process step, or may be filled with differing materials in different steps utilizing masking materials.

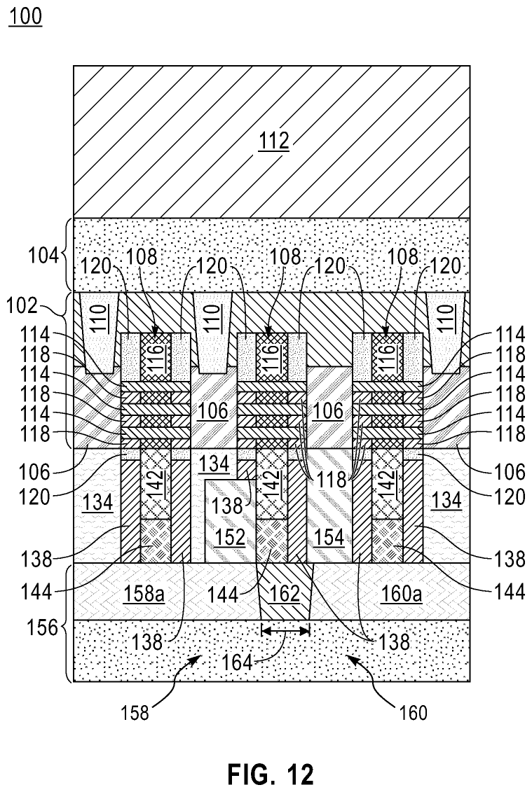

FIG. 12 is a schematic cross-sectional side view of the semiconductor structure 100 at a fabrication step, in accordance with one embodiment of the present invention. The semiconductor structure 100 at this stage includes a backside interconnect 156. The backside interconnect 156 is below the FEOL 102, and is made up of a plurality of signal lines 158 and a plurality of power lines 160. The plurality of signal lines 158 includes a first level signal line 158a, and the plurality of power lines includes a first level power line 160a. The first level signal line 158a and the first level power line 160a are separated by an interlayer dielectric (ILD) 162. In certain embodiments, the ILD 162 is fabricated as only the width of the bottom spacers 138. In the illustrated embodiment, on the other hand, the offset gate contact 152 enables the ILD 162 to increase a tip-to-tip distance 164 and negate any potential for flow between the first level signal line 158a and the first level power line 160a. The tip-to-tip distance 164, for example, is greater than a width of the gates 108, which is sufficient to prevent flow between the first level signal line 158a and the first level power line 160a. The offset gate contact 152 is thus electrically connected between the first gate 108 and the first level signal line 158a. The offset gate contact 152 is located directly below the first S/D 106.

The gate signals thus flow from the plurality of power lines 160 to the first level power line 160a, and then to the offset gate contact 152 and through a lateral side to the backside gate extensions 142 to control the signal at the HKMG 116. Contact through the lateral sides does not produce additional resistance, but does enable a more distanced location for the offset gate contact 152. The more distanced location enables better tip-to-tip flow control between the first level signal line 158a and the first level power line 160a. Controlling the signal to the HKMG 116 enables flow of the power signals to/from the contacts 110 to the S/Ds 106 (i.e., by way of the nanosheets 114) and then through the bottom S/D contact 154 to the plurality of power lines 160 within the backside interconnect 156.

The methods described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a front-end-of-line (FEOL) comprising a first source/drain (S/D) adjacent to a first gate;
a backside interconnect below the FEOL, comprising a plurality of signal lines and a plurality of power lines; and
an offset gate contact electrically connected between the first gate and a first signal line of the plurality of signal lines, wherein the offset gate contact is located directly below the first S/D.

2. The semiconductor structure of claim 1, further comprising a frontside back-end-of-line (BEOL) above the FEOL comprising signal processing layers.

3. The semiconductor structure of claim 1, further comprising a backside gate extension directly below the first gate, and electrically connected between the first gate and the offset gate contact.

4. The semiconductor structure of claim 3, further comprising a backside gate extension cap directly below the backside gate extension.

5. The semiconductor structure of claim 4, further comprising a backside S/D dielectric below the first S/D, wherein the backside S/D dielectric and the backside gate extension cap comprise different dielectric materials.

6. The semiconductor structure of claim 1, further comprising a second S/D adjacent to the first gate, wherein the second S/D is electrically connected to the backside interconnect through a S/D contact directly below the second S/D.

7. The semiconductor structure of claim 6, further comprising a spacer and a backside gate extension cap between the S/D contact and the offset gate contact.

8. A method, comprising:
forming a front-end-of-line (FEOL) comprising a first source/drain (S/D) and a first gate; and
forming an offset gate contact electrically connected between the first gate and a first signal line, wherein the offset gate contact is located directly below the first S/D.

9. The method of claim 8, further comprising forming a frontside back-end-of-line (BEOL) above the FEOL comprising signal processing layers.

10. The method of claim 8, further comprising forming a backside gate extension below the first gate, wherein the offset gate contact contacts a lateral side of the backside gate extension.

11. The method of claim 10, further comprising:
depositing a first dielectric material below the first S/D; and
depositing a second dielectric material below the backside gate extension, wherein the first dielectric material is etch selective from the second dielectric material.

12. The method of claim 11, further comprising forming a bottom spacer between the backside gate extension and the first dielectric material.

13. The method of claim 8, further comprising forming a bottom S/D contact below a second S/D adjacent to the first gate.

14. A semiconductor structure, comprising:
a first gate;
a first source/drain (S/D) adjacent to the first gate, and connected to a back-end-of-line (BEOL) through a S/D contact directly above the first S/D; and
an offset gate contact electrically connected between the first gate and a first level signal line, wherein the offset gate contact is located directly below the first S/D.

15. The semiconductor structure of claim 14, further comprising a backside gate extension directly below the first gate, and electrically connected between the first gate and the offset gate contact.

16. The semiconductor structure of claim 15, further comprising a backside gate extension cap directly below the backside gate extension.

17. The semiconductor structure of claim 16, further comprising a backside S/D dielectric below the first S/D, wherein the backside S/D dielectric and the backside gate extension cap comprise different dielectric materials.

18. The semiconductor structure of claim 14, further comprising a second S/D adjacent to the first gate, wherein the second S/D is electrically connected to a first level power line through a S/D contact directly below the second S/D.

19. The semiconductor structure of claim 14, further comprising a bottom spacer and a backside gate extension cap between the S/D contact and the offset gate contact.

20. The semiconductor structure of claim 14, further comprising:
a first level signal line; and
a first level power line, wherein a tip-to-tip distance between the first level signal line and the first level power line is greater than a width of the first gate.

21. A semiconductor structure, comprising:
a first gate comprising a high-k metal gate (HKMG) configured to activate nanosheet channels;
a gate extension extending vertically from the HKMG; and
an offset gate contact laterally adjacent to the gate extension.

22. The semiconductor structure of claim 21, wherein the offset gate contact is electrically connected to a first signal line of a backside interconnect.

23. The semiconductor structure of claim 22, wherein the backside interconnect comprises a first power line.

24. A semiconductor structure, comprising:
a first source/drain (S/D);
a first gate adjacent to the first S/D;
an offset gate contact electrically connected between the first gate and a first signal line of the plurality of signal lines, wherein the offset gate contact is located directly below the first S/D.

25. The semiconductor structure of claim 24, further comprising a backside gate extension directly below the first gate, and electrically connected between the first gate and the offset gate contact.
